(19) United States
(12) Patent Application Publication
(10) Pub. No.: US 2014/0048766 A1
(43) Pub. Date: Feb. 20, 2014

(54) METHOD FOR FABRICATING LIGHT EMITTING DIODE (LED) DICE USING BOND PAD DAM AND WAVELENGTH CONVERSION LAYERS

(71) Applicants: Chen-Fu CHU, Hsinchu City (TW); Feng-Hsu FAN, Jhonghe City (TW)

(72) Inventors: Chen-Fu CHU, Hsinchu City (TW); Feng-Hsu FAN, Jhonghe City (TW)

(73) Assignee: SemiLEDS Optoelectronics Co., Ltd., Chu-Nan (TW)

(21) Appl. No.: 13/585,968

(22) Filed: Aug. 15, 2012

(51) Int. Cl. H01L 33/06; H01L 33/50

(52) U.S. Cl. 257/13; 438/29; 257/E33.06; 257/E33.008

(57) ABSTRACT

A method for fabricating light emitting diode (LED) dice includes the step of forming a light emitting diode (LED) die having a multiple quantum well (MQW) layer configured to emit electromagnetic radiation, and a confinement layer on the multiple quantum well (MQW) layer having a wire bond pad. The method also includes the steps of forming a dam on the wire bond pad configured to protect a wire bond area on the wire bond pad, forming an adhesive layer on the confinement layer and the wire bond pad with the dam protecting the wire bond area, and forming a wavelength conversion layer on the adhesive layer. A light emitting diode (LED) die includes the dam on the wire bond pad, the adhesive layer on the confinement layer and the wavelength conversion layer on the adhesive layer configured to convert the electromagnetic radiation to a second spectral region.

### BACKGROUND

This disclosure relates generally to light emitting diodes (LED) dice having wavelength conversion layers and to a method for fabricating light emitting diode (LED) dice with wavelength conversion layers.

Light emitting diode (LED) dice have been developed that produce white light. In order to produce white light, a blue (LED) die can be used in combination with a wavelength conversion layer, such as a phosphor layer formed on the surface of the die. The electromagnetic radiation emitted by the blue (LED) die excites the atoms of the wavelength conversion layer, which converts some of the electromagnetic radiation in the blue wavelength spectral region to the yellow wavelength spectral region. The ratio of the blue to the yellow can be manipulated by the composition and geometry of the wavelength conversion layer, such that the output of the light emitting diode (LED) die appears to be white light.

In this type of light emitting diode (LED) die, the wavelength conversion layer can affect the fabrication of other elements of the die. For example, an adhesive layer can be used for attaching the wavelength conversion layer to the die. However, the adhesive layer can contaminate wire bond pads, making subsequent wire bonding to the pads difficult to perform and the resultant wire bonds substandard. In addition, the wire bonding process often depends on pattern recognition techniques in which the locations of the wire bond pads may be difficult to ascertain.

The present disclosure provides a method for fabricating light emitting diode (LED) dice by forming bond pad dams and then forming wavelength conversion layers with bond pads protected by the bond pad dams. Using the method, light emitting diode (LED) dice can be fabricated to produce white light having controlled color characteristics and high quality wire bonds.

### SUMMARY

A method for fabricating light emitting diode (LED) dice includes the step of forming a light emitting diode (LED) die having a multiple quantum well (MQW) layer configured to emit electromagnetic radiation in a first spectral region, and a confinement layer on the multiple quantum well (MQW) layer having a wire bond pad. The method also includes the steps of forming a dam on the wire bond pad configured to protect a wire bond area on the wire bond pad; forming an adhesive layer on the confinement layer and the wire bond pad with the dam protecting the wire bond area; and forming a wavelength conversion layer on the adhesive layer configured to convert the electromagnetic radiation in the first spectral region to output electromagnetic radiation in a second spectral region. The method also includes the step of wire bonding a wire to the wire bond area on the wire bond pad, and can include the step of using the dam during the wire bonding step for automatic pattern recognition.

A light emitting diode (LED) die includes a multiple quantum well (MQW) layer configured to emit electromagnetic radiation in a first spectral region and a confinement layer on the multiple quantum well (MQW) layer having a wire bond pad. The (LED) die also includes a dam on the wire bond pad configured to protect a wire bond area on the wire bond pad, an adhesive layer on the confinement layer and the wire bond pad with the dam protecting the wire bond area, and a wavelength conversion layer on the adhesive layer configured to convert the electromagnetic radiation in the first spectral region to output electromagnetic radiation in a second spectral region.

### BRIEF DESCRIPTION OF THE DRAWINGS

FIGS. 1A-1E are schematic cross sectional views illustrating steps in a method for fabricating a vertical light emitting diode (VLED) die having a wavelength conversion layer and a bond pad dam;

FIG. 2A is a schematic plan view taken along line 2A-2A of FIG. 1A illustrating a bond pad on the vertical light emitting diode (VLED) die;

FIG. 2B is a schematic plan view taken along line 2B-2B of FIG. 1B illustrating a bond pad dam on the bond pad;

FIG. 2C is a schematic plan view taken along line 2C-2C of FIG. 1C illustrating an adhesive layer on the bond pad and the vertical light emitting diode (VLED) die;

FIG. 2D is a schematic plan view taken along line 2D-2D of FIG. 1D illustrating a wavelength conversion layer on the adhesive layer;

FIG. 3A is a schematic cross sectional view illustrating a wavelength conversion layer having a substrate;

FIG. 3B is a schematic cross sectional view illustrating a substrate free wavelength conversion layer;

FIG. 3C is a schematic cross sectional view illustrating a wavelength conversion layer having wavelength conversion particles and reflective particles;

FIG. 4A is a schematic plan view illustrating a bond pad dam having an elliptical shape;

FIG. 4B is a schematic plan view illustrating a bond pad dam having an rectangular or square shape;

FIG. 4C is a schematic plan view illustrating a bond pad dam having a u-shape;

FIG. 4D is a schematic plan view illustrating a bond pad dam having a half circle or half elliptical shape; and

FIG. 5 is a schematic perspective view of a SEM picture illustrating a bond pad dam and a wire bond on a bond pad.

### DETAILED DESCRIPTION

It is to be understood that when an element is stated as being “on” another element, it can be directly on the other element or intervening elements can also be present. However, the term “directly” means there are no intervening elements. In addition, although the terms “first”, “second” and “third” are used to describe various elements, these elements should not be limited by the term. Also, unless otherwise defined, all terms are intended to have the same meaning as commonly understood by one of ordinary skill in the art.

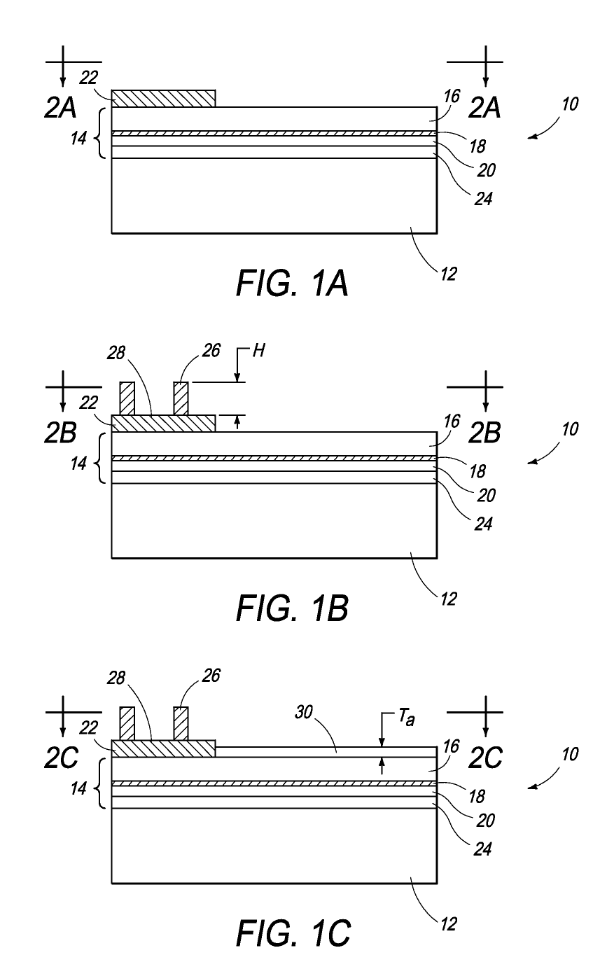

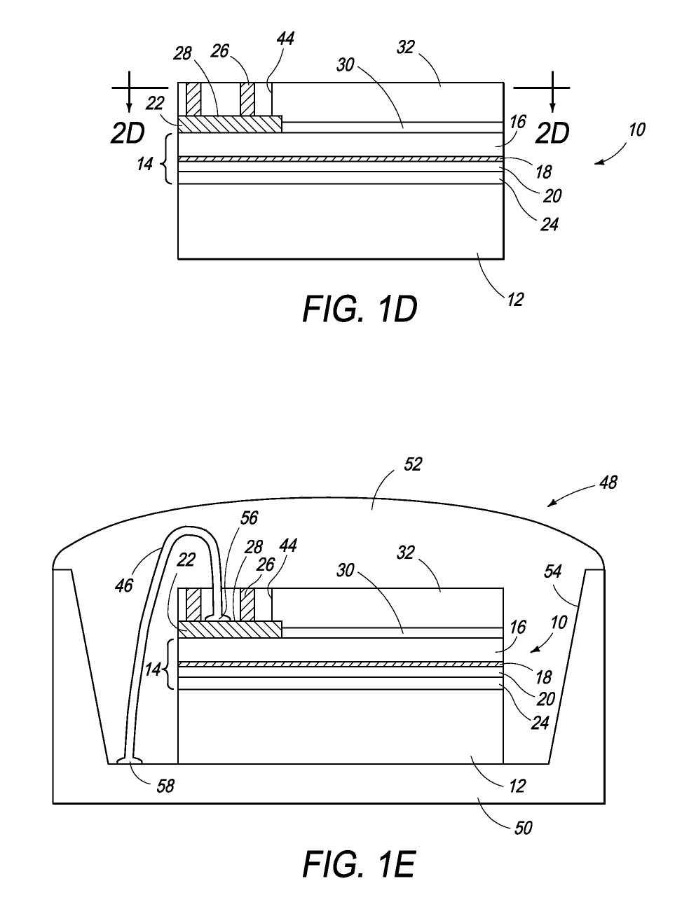

Referring to FIG. 1A-1E, steps in a method for fabricating a vertical light emitting diode (VLED) die 10 are illustrated. For simplicity various elements of the vertical light emitting diode (LED) die 10 are not illustrated. However, this type of vertical light emitting diode (VLED) die is further described in U.S. Pat. Nos. 7,195,944 and 7,615,789, both of which are incorporated herein by reference. Although the vertical light emitting diode (VLED) die 10 is described, it is to be understood that the concepts described herein can also be applied to other types of light emitting diode (LED) dice, such as ones with planar electrode configurations. In addition, although the method is shown being performed on a single die, it is to be understood that the method can be performed at the wafer level on a wafer containing multiple dice, which can be singulated into individual dice following the fabrication process.

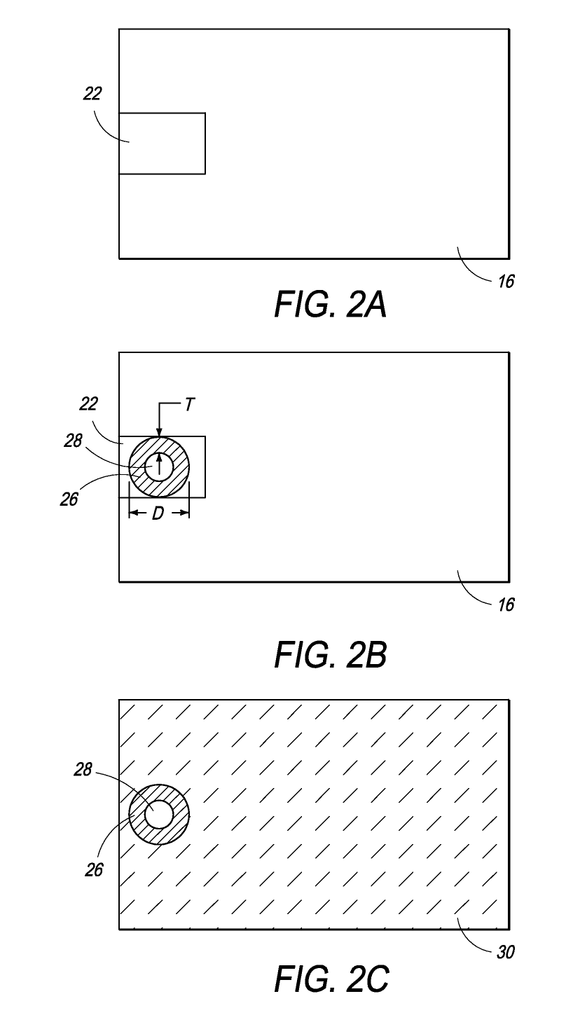

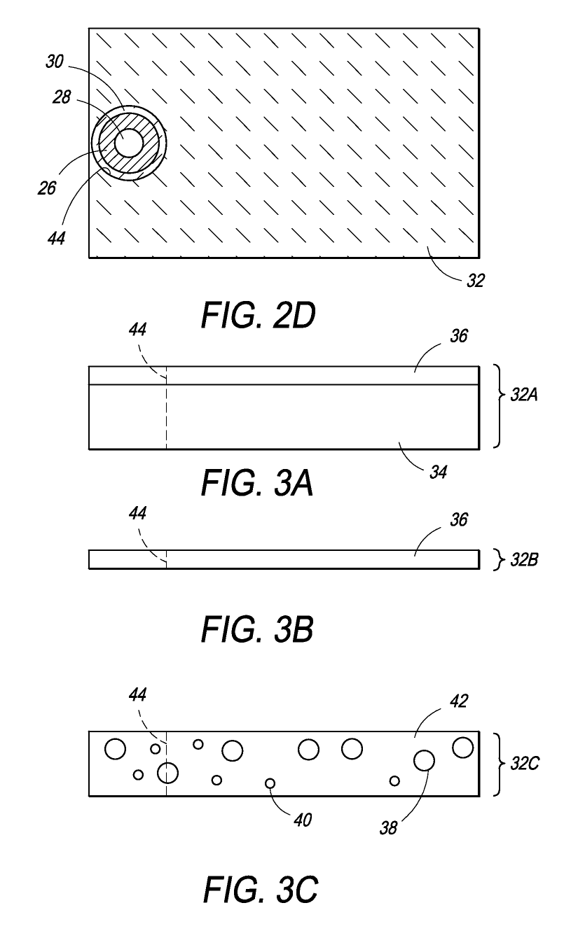

Initially, as shown in FIGS. 1A and 2A, the method includes the step of forming (or alternately providing) the vertical light emitting diode (VLED) die 10 with a conductive substrate 12, and an epitaxial stack 14 on the conductive substrate 12. The epitaxial stack 14 includes an n-type confinement layer 16, a multiple quantum well (MQW) layer 18 in electrical contact with the n-type confinement layer 16 configured to emit electromagnetic radiation, and a p-type confinement layer 20 in electrical contact with the multiple quantum well (MQW) layer 18.

The n-type confinement layer 16 preferably comprises n-GaN. Other suitable materials for the n-type confinement layer 16 include n-AlGaN, n-InGaN, n-AlInGaN, AlInN and n-AlN. The multiple quantum well (MQW) layer 18 preferably includes one or more quantum wells comprising one or more layers of InGaN/GaN, AlGaInN, AlGaN, AlInN and AN. The multiple quantum well (MQW) layer 18 can be configured to emit electromagnetic radiation from the visible spectral region (e.g., 400-770 nm), the violet-indigo spectral region (e.g., 400-450 nm), the blue spectral region (e.g., 450-490 nm), the green spectral region (e.g., 490-560 nm), the yellow spectral region (e.g., 560-590 nm), the orange spectral region (e.g., 590-635 nm) or the red spectral region (e.g., 635-700 nm). The p-type confinement layer 20 preferably comprises p-GaN. Other suitable materials for the p-type confinement layer 20 include p-AlGaN, p-InGaN, p-AlInGaN, p-AlInN and p-AlN.

Still referring to FIG. 1A, the vertical light emitting diode (VLED) die 10 also includes an n-bond pad 22 on the n-type confinement layer 16 and a reflector layer 24 on the conductive substrate 12. The n-bond pad 22 can have a size, peripheral shape and location suitable for wire bonding. As shown in FIG. 2A, the n-bond pad 22 can have a generally rectangular shape, or any other suitable peripheral shape (e.g., polygonal, circular or elliptical). In addition, the n-bond pad 22 can comprise a conductive wire bondable material, such as a single layer of a metal such as Al, Ti, Ni, Au, Pt, Ag or Cr, or a metal stack such as Ti/Al/Ni/Au, Al/Ni/Au, Ti/Al/Pt/Au or Al/Pt/Au. The reflector layer 24 can comprise a single layer of a highly reflective material such as Ag, Si or Al, or multiple layers, such as Ni/Ag/Ni/Au, Ag/Ni/Au, Ti/Ag/Ni/Au, Ag/Pt, Ag/Pd or Ag/Cr. All of the elements of the vertical light emitting diode (VLED) die 10 described so far can be fabricated using techniques that are known in the art.

Next, as shown in FIGS. 1B and 2B, the method includes the step of forming a dam 26 on the n-bond pad 22. The dam 26 can comprise an organic or a non-organic material deposited on the n-bond pad 22 using a suitable deposition process. Suitable materials for the dam 26 include polymer materials such as epoxy, silicone, polyimide, parylene and benzocyctobutene (BCB). In addition, these polymer materials can include fillers such as silicates, configured to reduce the coefficient of thermal expansion (CTE) and adjust the viscosity of the polymer material. The dam 26 can also comprise an acrylic, a polyacrylamide (PC), a poly methyl methacrylate (PMMA), a glass, a silicone or a quartz material. As another alternative, the dam 26 can comprise an imageable material such as a photo resist, such as “EPON RESIN SU-8”. The dam 26 can also comprise a metal such as Al, Ti, Ag, Au, Cu, Cr, Ni, Co or TiW.

The dam 26 encloses a wire bond area 28 on the n-bond pad 22 and is configured to define, locate and protect the wire bond area 28. In addition, the dam is configured to provide a target for automatic pattern recognition during subsequent wire bonding to the n-bond pad 22. Suitable processes for forming the dam 26 include spin-coating, lithography, dip-coating, dispensing using a material dispensing system, printing, jetting, spraying, chemical vapor deposition (CVD), thermal evaporation, e-beam evaporation and adhesive. In addition, the dam 26 can comprise a single layer of material or multiple layers of material. The dam 26 preferably is formed with a size and peripheral shape that falls within the boundaries of the n-bond pad 22. The width, length and diameter of the dam 26 can be selected as required, with from about 10 to 1000 μm for a side or a diameter being representative. A height H (or thickness) of the dam 26 on the n-bond pad 22 can also be selected as required, with from at least 500 Å to 100 μm being representative. As will be further explained the size and shape of the dam are selected to protect the wire bond area 28 during a subsequent adhesive layer forming step.

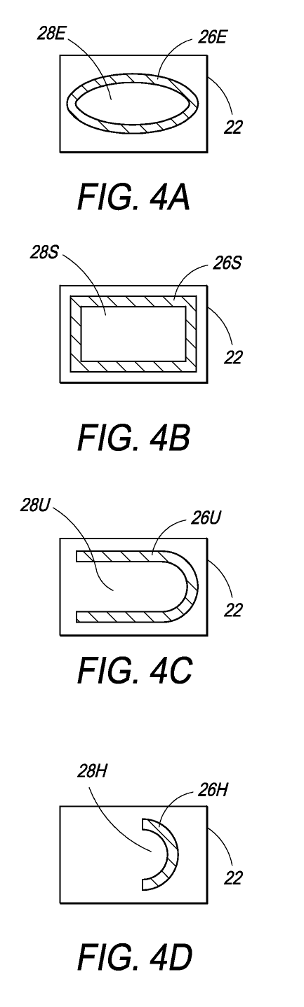

Suitable peripheral shapes for the dam 26 include circular, polygonal, elliptical, peanut, oval, square, rectangular and oblong. As another alternative, the dam 26 can be open ended with a half-circle, half elliptical, u-shape or v-shape. As shown in FIG. 2B, the dam 26 can comprise a donut having a circular peripheral shape with a diameter of D and a wall thickness of T. The circular peripheral shape of the dam 26 also defines the wire bond area 28 with a circular peripheral shape. FIGS. 4A-4D illustrate alternate peripheral shapes including an elliptical dam 26E (FIG. 4A) enclosing a circular wire bond area 28E, a rectangular (or square) dam 26S (FIG. 4B) enclosing a rectangular (or square) wire bond area 28S, an open ended u-shaped (or v-shaped) dam 26U (FIG. 4C) partially enclosing a wire bond area 28U, and an open ended half circle (or half elliptical) dam 26H partially enclosing a wire bond area 28H. As another alternative, a dam can be formed on multiple n-bond pads to enclose multiple wire bond areas.

Next, as shown in FIGS. 1C and 2C, the method includes the step of forming an adhesive layer 30 on the n-type confinement layer 16 and on portions of the n-bond pad 22 not enclosed by the dam 26. The dam 26 prevents the adhesive layer 30 from covering or contaminating the wire bond area 28 on the n-bond pad 22. The adhesive layer 30 can comprise a suitable adhesive formed using a suitable process such as dispensing, screen-printing, spin coating, nozzle deposition or spraying. Suitable adhesives include silicone, epoxy and acrylic glue. A thickness Ta of the adhesive layer preferably is less than the height H of the dam 26 with from 200 Å to 50 μm being representative. As shown in FIG. 2C, the adhesive layer 30 can substantially cover the surface of the n-type confinement layer 16 but does not cover or contaminate the wire bond area 28 on the n-bond pad 22.

Next, as shown in FIGS. 1D and 2D, the method includes the step of forming a wavelength conversion layer 32 on the adhesive layer 30. As shown in FIG. 2D, the wavelength conversion layer 32 can include an opening 44 aligned with the n-bond pad 22 for providing access to the n-bond pad 22. As also shown in FIG. 2D, the wavelength conversion layer 32 can have a peripheral shape that substantially matches the peripheral shape of the vertical light emitting diode (VLED) die 10. The wavelength conversion layer 32 is configured to convert at least some of the electromagnetic radiation emitted by the multiple quantum well (MQW) layer 18 into electromagnetic radiation having a different wavelength range, such as a higher wavelength range. For example, if the multiple quantum well (MQW) layer 18 emits electromagnetic radiation in a blue spectral range, the wavelength conversion layer 32 can be configured to convert at least some of this radiation to a yellow spectral range, such that the output of the vertical light emitting diode (VLED) die 10 appears to be white light.

FIGS. 3A-3C illustrate different configurations of wavelength conversion members 32A-32C for forming the wavelength conversion layer 32. The wavelength conversion members 32A-32C comprise discrete components configured for placement on the adhesive layer 30 to form the wavelength conversion layer 32 in the vertical light emitting diode (VLED) die 10. The wavelength conversion members 32A-32C can be placed on the adhesive layer 30 using a pick and place mechanism such as one used in semiconductor manufacture to handle discrete semiconductor die. In this case the mechanism will perform a pick and press operation to also press the wavelength conversion members 32A-32C into the adhesive layer 30.

As shown in FIG. 3A, a wavelength conversion member 32A includes a transparent substrate 34 and a wavelength conversion material 36. The wavelength conversion material 36 can comprise a transparent base material such as a polymer, a glass, or a ceramic containing a wavelength conversion compound, such as a phosphor compound. In addition, the wavelength conversion compound can be incorporated into the base material, using a mixing process to form a viscous mixture. Exemplary base materials for the wavelength conversion material 36 include silicone, epoxy, spin on glass (SOG), SiO₂, and Al₂O₃ in liquid or viscous form, which can be mixed with the wavelength conversion compound in a specific ratio. Exemplary wavelength conversion compounds for the wavelength conversion material 36 include YAG:Ce, TAG:Ce, alkaline earth silicon nitride doped with Eu, alkaline earth silicate doped with Eu, or calcium scandate doped with Ce. Other suitable wavelength conversion materials are further described in the previously cited U.S. Pat. Nos. 7,195,944 and 7,615,789. The mixture can then be applied to the transparent substrate 34, using a coating process such as dip coating, spin coating, rod coating, blade coating, knife coating, air knife coating, Gravure coating, roll coating or slot and extrusion coating. Following the coating process, the mixture can be cured to solidify the wavelength conversion material 36. The opening 44 can be made using a suitable process such as punching or etching.

As shown in FIG. 3B, a substrate free wavelength conversion member 32B can include the wavelength conversion material 36 but without the transparent substrate 34 (FIG. 3A). The substrate free wavelength conversion member 32B can be made by peeling the transparent substrate 34 away from the wavelength conversion material 36 using a release film or by direct extrusion. An exemplary release film comprises a fluoropolymer resin manufactured by AGC Chemicals Americas, Inc. under the trademark FLUON.

As shown in FIG. 3C, a particle wavelength conversion member 32C includes wavelength conversion particles 38 and reflective particles 40 embedded in a base material 42. The base material 42 can comprise a transparent base material such as a polymer, a glass, or a ceramic containing the wavelength conversion particles 38 and the reflective particles 40. Suitable materials for the wavelength conversion particles 38 include phosphor compounds such as YAG:Ce, TAG:Ce, alkaline earth silicon nitride doped with Eu, alkaline earth silicate doped with Eu, and calcium scandate doped with Ce. Suitable materials for the reflective particles 40 include TiO₂, Al₂O₃ and SiO₂. In addition, the wavelength conversion particles 38 and the reflective particles 40 can have a diameter of from about 8 μm to 40 μm and a weight percentage in the base material 42 of from 10 wt % to 85 wt %.

As shown in FIG. 1D, following formation of the wavelength conversion layer 32, the vertical light emitting diode (VLED) die 10 includes the dam 26 on the n-bond pad 22, which has protected the wire bond area 28 during the formation of the adhesive layer 30 and the attachment of the wave length conversion layer 32. During the wire bonding step to follow, the wire bond area 28 will be free of contaminants, particularly any material from the adhesive layer 30. In addition, the dam 26 provides improved pattern recognition by automated wire bonding equipment used in the wire bonding step to follow.

Next, as shown in FIG. 1E, the method includes the step of wire bonding a wire 46 to the wire bond area 28 on the n-bond pad 22. By way of example and not limitation, the wire bonding step can be performed during formation of a light emitting diode (LED) package 48 (FIG. 1E). The light emitting diode (LED) package 48 includes a substrate 50, the vertical light emitting diode (VLED) die 10 mounted to the substrate 50, and an electrically insulating, light transmissive encapsulating layer 52 which encapsulates the vertical light emitting diode (VLED) die 10. The substrate 50 can comprise a semiconductor material, such as silicon (Si), or another material, such GaAs, SiC, AN, Al₂O₃, or sapphire. The substrate 50 includes a cavity 54 wherein the vertical light emitting diode (VLED) die 10 is mounted. As shown in FIG. 1E, the wire 46 includes a first wire bond 56 on the wire bond area 28 and a second wire bond 58 on the substrate 50. The first wire bond 56 has been protected from contamination by the dam 26. In addition, the dam 26 has provided a visible target for automated wire bonding during formation of the first wire bond 56.

Example

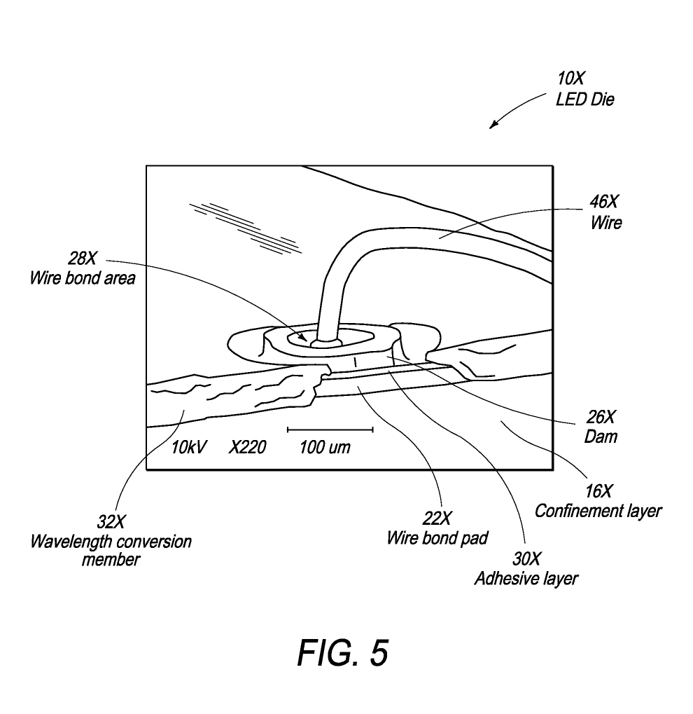

FIG. 5 is a drawing of a SEM picture illustrating a light emitting diode (LED) die 10X fabricated using the method. The voltage for the SEM was 10 kV, the magnification was ×220 and the 100 μm scale is shown. The light emitting diode (LED) die 10X includes a dam 26X protecting a wire bond area 28X on a wire bond pad 22X. As also shown in the FIG. 5, an adhesive layer 30X on a confinement layer 16X contacts the dam 26X but not the wire bond area 28X. In addition, a wavelength conversion layer 32X has been formed on the adhesive layer 30X by placement of a pre-formed wavelength conversion member 32A (FIG. 3A) or 32B (FIG. 3B) or 32C (FIG. 3C) on the adhesive layer 30X. Other parameters of this

### Example include

1. Adhesive layer 30X comprising silicone deposited to a thickness of about 10 μm using a dispensing process.

2. Wavelength conversion layer 32X comprising phosphor formed using blade coating and placed using a pick and press operation.

3. Dam 26X comprising polymer formed using a photolithography process having a circular peripheral shape with a diameter (D) of about 160 μm and a height (H) of about 70 μm.

4. Wire bond pad 22X comprising Au having a size on a side of 410 μm.

5. Wire 46X comprising Au having a diameter of 1.25 mil.

6. Wire bonding performed using an iHawk or iHawk Xtreme wire bonder manufactured by ASM Pacific Technology Ltd.

Thus the disclosure describes an improved method for fabricating light emitting diode (LED) dice with wavelength conversion layers, and improved light emitting diode dice fabricated using the method. While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

What is claimed is:

1. A method for fabricating light emitting diode (LED) dice comprising:
forming a light emitting diode (LED) die having a multiple quantum well (MQW) layer configured to emit electromagnetic radiation in a first spectral region, and a confinement layer on the multiple quantum well (MQW) layer having a wire bond pad;
forming a dam on the wire bond pad configured to protect a wire bond area on the wire bond pad;
forming an adhesive layer on the confinement layer and the wire bond pad with the dam protecting the wire bond area;
forming a wavelength conversion layer on the adhesive layer configured to convert the electromagnetic radiation in the first spectral region to output electromagnetic radiation in a second spectral region; and
wire bonding a wire to the wire bond area on the wire bond pad.

2. The method of claim 1 further comprising using the dam during the wire bonding step for automatic pattern recognition.

3. The method of claim 1 wherein the forming the wavelength conversion layer step comprises placing a pre-formed wavelength conversion member on the adhesive layer.

4. The method of claim 1 wherein the forming the wavelength conversion layer step comprises mixing a wavelength conversion material with a base material to form a mixture, coating the mixture on a release film, curing the mixture, separating a wavelength conversion member from the release film, and placing the wavelength conversion member on the adhesive layer.

5. The method of claim 4 wherein the coating the mixture on the release film step comprise a process selected from the group consisting of dip coating, rod coating, blade coating, knife coating, air knife coating, Gravure coating, roll coating, and slot and extrusion coating.

6. The method of claim 1 wherein the wavelength conversion layer comprises a transparent substrate and a wavelength conversion material on the transparent substrate.

7. The method of claim 1 wherein the wavelength conversion layer comprises a base material containing a plurality of wavelength conversion particles and reflective particles.

8. The method of claim 1 wherein the wavelength conversion layer comprises a substrate free wavelength conversion material.

9. The method of claim 1 wherein the first spectral region comprises a blue spectral region and the second spectral region comprises a yellow spectral region.

10. The method of claim 1 wherein the forming the dam step comprises a method selected from the group consisting of spin-coating, lithography, dip-coating, dispensing using a material dispensing system, printing, jetting, spraying, chemical vapor deposition (CVD), thermal evaporation, e-beam evaporation and adhesive.

11. The method of claim 1 wherein the (LED) die comprises a vertical light emitting diode (VLED) die, the confinement layer comprises an n-type confinement layer and the wire bond pad comprises an n-bond pad.

12. A method for fabricating light emitting diode (LED) dice comprising:
forming or providing a vertical light emitting diode (VLED) die comprising an n-type confinement layer having an n-type wire bond pad, a multiple quantum well (MQW) layer configured to emit electromagnetic radiation in a first spectral region, and a p-type confinement layer;
forming a dam on the wire bond pad configured to protect a wire bond area on the wire bond pad;
forming an adhesive layer on the confinement layer and the wire bond pad with the dam protecting the wire bond area;
forming a wavelength conversion member comprising a wavelength conversion material configured to convert the electromagnetic radiation in the first spectral region to output electromagnetic radiation in a second spectral region;
placing the wavelength conversion member on the adhesive layer; and
wire bonding a wire to the wire bond area on the wire bond pad.

13. The method of claim 12 further comprising using the dam during the wire bonding step for automatic pattern recognition.

14. The method of claim 12 further comprising forming an opening in the wavelength conversion member prior to the placing step configured to encircle the dam.

15. The method of claim 12 wherein the forming the wavelength conversion member step comprises mixing a wavelength conversion material with a base material to form a mixture, coating the mixture on a release film, curing the mixture, separating the wavelength conversion member from the release film

16. The method of claim 12 wherein the forming the wavelength conversion member step comprises depositing a wavelength conversion material on a transparent substrate.

17. The method of claim 12 wherein the forming the wavelength conversion member step comprises incorporating a plurality of wavelength conversion particles and reflective particles in a base material.

18. The method of claim 12 wherein the first spectral region comprises a blue spectral region and the second spectral region comprises a yellow spectral region.

19. The method of claim 12 wherein the forming the dam step comprises a method selected from the group consisting of spin-coating, lithography, dip-coating, dispensing using a material dispensing system, printing, jetting, spraying, chemical vapor deposition (CVD), thermal evaporation, e-beam evaporation and adhesive.

20. The method of claim 12 wherein the dam has a shape selected from the group consisting of circular, polygonal, elliptical, peanut, oval, square, rectangular, oblong, half-circle, half elliptical, u-shape and v-shape.

21. The method of claim 12 wherein the dam has a height of greater than 500 Å.

22. The method of claim 12 wherein the forming the adhesive layer step comprises a process selected from the group consisting of screen printing, spin coating, nozzle deposition and spraying.

23. The method of claim 12 wherein the adhesive comprises a material selected from the group consisting of silicone, epoxy and acrylic glue.

24. A light emitting diode (LED) die comprising:
a multiple quantum well (MQW) layer configured to emit electromagnetic radiation in a first spectral region,
a confinement layer on the multiple quantum well (MQW) layer having a wire bond pad;
a dam on the wire bond pad configured to protect a wire bond area on the wire bond pad;
an adhesive layer on the confinement layer and the wire bond pad with the dam protecting the wire bond area;
a wavelength conversion layer on the adhesive layer configured to convert the electromagnetic radiation in the first spectral region to output electromagnetic radiation in a second spectral region.

25. The light emitting diode (LED) die of claim 24 wherein the (LED) die comprises a vertical light emitting diode (VLED) die, the confinement layer comprises a n-type confinement layer and the wire bond pad comprises an n-bond pad.

26. The light emitting diode (LED) die of claim 24 wherein the wavelength conversion layer comprises a transparent substrate and a wavelength conversion material on the transparent substrate.

27. The light emitting diode (LED) die of claim 24 wherein the wavelength conversion layer comprises a base material containing a plurality of wavelength conversion particles and reflective particles.

28. The light emitting diode (LED) die of claim 24 wherein the wavelength conversion layer comprises a substrate free wavelength conversion material.

29. The light emitting diode (LED) die of claim 24 wherein the first spectral region comprises a blue spectral region and the second spectral region comprises a yellow spectral region.

30. The light emitting diode (LED) die of claim 24 wherein the dam is formed on a plurality of wire bond pads and protects a plurality of wire bond areas.
